(19) United States
(12) Patent Application Publication
(10) Pub. No.: US 2018/0074126 A1
(43) Pub. Date: Mar. 15, 2018

(54) APPARATUS AND METHOD FOR EMPLOYING MUTUALLY EXCLUSIVE WRITE AND READ CLOCK SIGNALS IN SCAN CAPTURE MODE FOR TESTING DIGITAL INTERFACES

(71) Applicant: QUALCOMM Incorporated, San Diego, CA (US)

(72) Inventors: Bilal Zafar, San Diego, CA (US); Rakesh Vattikonda, San Diego, CA (US); De Lu, San Diego, CA (US); Venkatasubramanian Narayanan, San Diego, CA (US); Masoud Zamani, San Diego, CA (US); Joseph Fang, San Diego, CA (US)

(21) Appl. No.: 15/263,059

(22) Filed: Sep. 12, 2016

(51) Int. Cl. G01R 31/317; G11C 7/22; G01R 31/3177

(52) U.S. Cl. CPC G01R 31/31727; G01R 31/3177; G01R 31/31704; G11C 7/22

(57) ABSTRACT

An apparatus and method of employing mutually exclusive write and read clocks in scan capture mode for testing digital interfaces. The apparatus includes a first circuit and a first clock generator configured to generate a first clock signal for transferring a test sample from an input to an output of the first circuit in response to the first clock signal during each of a first set of scan capture cycles; a second circuit and a second clock generator configured to generate a second clock signal for transferring the test sample from an input to an output of the second circuit in response to the second clock signal during each of a second set of scan capture cycle; the first clock signal being suppressed during each scan capture cycle of the second set, and the second clock signal being suppressed during each scan capture cycle of the first set.

### BACKGROUND

Field

Aspects of the present disclosure relate generally to design for testability (DFT) systems, and in particular, to an apparatus and method of employing mutually exclusive write and read clocks in scan capture mode for testing digital interfaces.

Background

A first core of an integrated circuit (IC) often processes data in a first voltage domain and a first clock domain. The IC may include a second core that processes data in a second voltage domain and second clock domain. Often, there is a need to transfer data from the first core to the second core. A digital interface is provided to perform the transfer of the data, including the conversion of the data from the first voltage domain to the second voltage domain, as well as from the first clock domain to the second clock domain.

There is a need to implement design for testability (DFT) in such digital interfaces. However, the data in the first core being in a first clock domain and the data in the second core being in a second clock domain complicates the DFT implementation.

### SUMMARY

The following presents a simplified summary of one or more embodiments in order to provide a basic understanding of such embodiments. This summary is not an extensive overview of all contemplated embodiments, and is intended to neither identify key or critical elements of all embodiments nor delineate the scope of any or all embodiments. Its sole purpose is to present some concepts of one or more embodiments in a simplified form as a prelude to the more detailed description that is presented later.

An aspect of the disclosure relates to an apparatus including a first circuit having a first input and a first output, and a first clock generator configured to generate a first clock signal, wherein the first circuit is configured to transfer a test pattern sample from the first input to the first output in response to the first clock signal during each of a first set of scan capture cycles. The apparatus also includes a second circuit including a second input and a second output; and a second clock generator configured to generate a second clock signal, wherein the second circuit is configured to transfer the test pattern sample from the second input to the second output in response to the second clock signal during each of a second set of scan capture cycle. The first clock generator is configured to suppress the first clock signal during each of the second set of scan capture cycles, and the second clock generator is configured to suppress the second clock signal during each of the first set of scan capture cycles.

Another aspect of the disclosure relates to a method including transferring a test pattern sample from a first input to a first output of a first circuit in response to a first clock signal during each of a first set of scan capture cycles; transferring the test pattern sample from a second input to a second output of a second circuit in response to second clock signal during each of a second set of scan capture cycle; suppressing the first clock signal during each of the second set of scan capture cycles; and suppressing the second clock signal during each of the first set of scan capture cycles.

Another aspect of the disclosure relates to an apparatus including means for transferring a test pattern sample from a first input to a first output of a first circuit in response to a first clock signal during each of a first set of scan capture cycles; means for transferring the test pattern sample from a second input to a second output of a second circuit in response to second clock signal during each of a second set of scan capture cycle; means for suppressing the first clock signal during each of the second set of scan capture cycles; and means for suppressing the second clock signal during each of the first set of scan capture cycles.

To the accomplishment of the foregoing and related ends, the one or more embodiments include the features hereinafter fully described and particularly pointed out in the claims. The following description and the annexed drawings set forth in detail certain illustrative aspects of the one or more embodiments. These aspects are indicative, however, of but a few of the various ways in which the principles of various embodiments may be employed and the description embodiments are intended to include all such aspects and their equivalents.

### BRIEF DESCRIPTION OF THE DRAWINGS

FIG. 1 illustrates a block diagram of an exemplary digital interface in accordance with an aspect of the disclosure.

FIG. 2 illustrates a block diagram of another exemplary digital interface in accordance with another aspect of the disclosure.

FIG. 3A illustrates a schematic diagram of exemplary controller for a digital interface in accordance with another aspect of the disclosure.

FIG. 3B illustrates a table depicting an input signal and corresponding gated clock signal associated with an operation of the digital interface controller in accordance with another aspect of the disclosure.

FIG. 3C illustrates a graph depicting several exemplary signals associated with an operation of the exemplary digital interface controller in accordance with another aspect of the disclosure.

FIG. 4 illustrates a flow diagram of an exemplary method of testing a digital interface in accordance with another aspect of the disclosure.

FIG. 5 illustrates a flow diagram of another exemplary method of testing a digital interface in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

Often at an interface between a first core of an integrated circuit (IC) (e.g., a digital signal processing (DSP) core) and a second core of the IC (e.g., a modem core), a digital interface is provided for transferring data from the first core to the second core. The first core may operate under a first voltage domain and a first clock domain, and the second core may operate under a second voltage domain and a second clock domain.

The digital interface would perform the required voltage level shifting for converting data from the first voltage domain to the second voltage domain. The digital interface would also perform the required conversion of the data from the first clock domain to the second clock domain. Examples of such digital interface are discussed below.

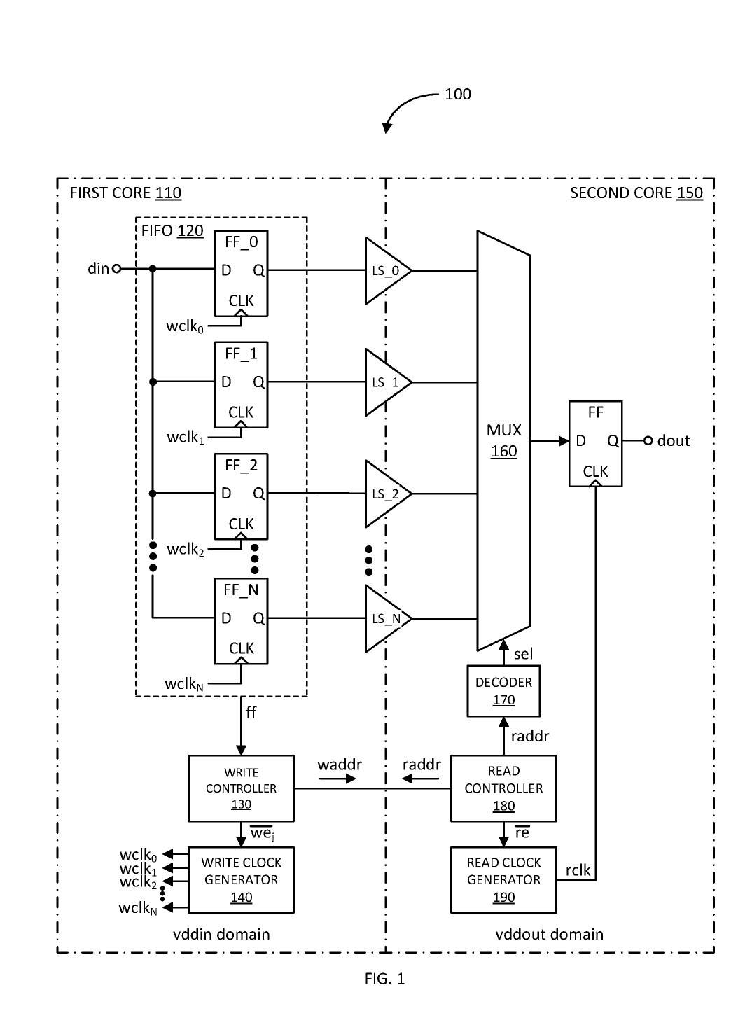

FIG. 1 illustrates a block diagram of an exemplary digital interface 100 in accordance with an aspect of the disclosure. The digital interface 100 includes a first core 110 and a second core 150. As discussed in more detail below, the digital interface 100 performs the transfer of input data din from the first core 110 to the second core 150 to generate output data dout.

In particular, the first core 110 includes a first-in-first-out (FIFO) memory 120 having a set of transmit flip-flops FF_0, FF_1, FF_2 to FF_N. Each of the transmit flip-flops FF_0 to FF_N includes a data input (D) configured to receive input data din. The transmit flip-flops FF_0, FF_1, FF_2 to FF_N include clock inputs (CLK) configured to receive write clock signals wclk₀, wclkⱼ, wclk₂ to wclk_{N}, respectively. The transmit flip-flops FF_0, FF_1, FF_2 to FF_N include data outputs (Q) configured to produce output data (by transferring the data din from the input (D) to the output (Q)) in response to triggering portions (e.g., edges) of the write clock signals wclk₀, wclkⱼ, wclk₂ to wclk_{N}, respectively.

More specifically, in functional mode, the write controller 130 generates the write clock enable signal w̅e̅_̅{̅J̅}̅ for selecting the jth write clock signal wclkⱼ among the set of write clock signals wclk₀ to wclk_{N} to be generated by the write clock generator 140. Thus, in response to the write clock enable signal w̅e̅_̅{̅J̅}̅, the write clock generator 140 generates (ungates) the corresponding write clock signal wclkⱼ and suppresses (gates) the remaining write clock signals during each functional mode cycle. During each functional mode cycle, an input data din is written from the input (D) to the output (Q) of the corresponding flip-flop FF_j.

The write controller 130 is further configured to stall the writing of the input data din to the FIFO memory 120 if the memory is full as indicated by an asserted FIFO full (ff) signal generated by the FIFO memory. The FIFO memory 120 is full when all of the flip-flops FF_0 to FF_N include outputs (Q) having valid data not yet read or received by the second core 150.

For transferring data from the first core 110 to the second core 150, the write controller 130 is configured to generate a write address waddr identifying one of the transmit flip-flops FF_0 to FF_N that has the next data to be transferred to the second core 150. The write controller 130 is configured to send the write address waddr to the second core 150 to inform the later that the identified transmit flip-flop includes data to be read or received by the second core 150. The write controller 130 is further configured to receive a read address raddr from the second core 150 when data at the output (Q) of the flip-flop identified by the read address raddr has been read or received by the second core 150. After receiving the read address raddr, the write controller 130 makes that flip-flop available to receive new input data din.

The data and signaling in the first core 110 may swing between voltage levels pertaining to a first voltage domain vddin. Similarly, the data and signaling in the second core 150 may swing between voltage levels pertaining to a second voltage domain vddout. If the first voltage domain vddin is different than the second voltage domain vddout, the digital interface 100 includes a set of level shifters LS_0, LS1, LS2 to LS_N configured to level shift the data at the outputs (Q) of the transmit flip-flops FF_0, FF_1, FF_2 to FF_N from the first voltage domain vddin to the second voltage domain vddout, respectively. If the first voltage domain vddin is substantially the same or similar to the second voltage domain vddout, the digital interface 100 need not include the set of level shifters LS_0 to LS_N. The level shifters LS_0 to LS_N may be implemented in the first core 110, the second core 150, or between the first and second cores.

The second core 150 includes a multiplexer (MUX) 160, a receive flip-flop FF, a decoder 170, a read controller 180, and a read clock generator 190. The multiplexer 160 includes inputs coupled to respective outputs of the level shifters LS_0 to LS_N if the level shifters are present. Otherwise, the inputs of the multiplexer 160 are coupled to the data outputs (Q) of the transmit flip-flops FF_0 to FF_N, respectively.

The multiplexer 160 includes an output coupled to a data input (D) of the receive flip-flop FF. The receive flip-flop FF includes a clock input (CLK) configured to receive a read clock signal rclk. The receive flip-flop FF is configured to transfer data at its data input (D) to a data output (Q) to produce an output data dout in response to a triggering portion (e.g., edge) of the receive clock signal rclk.

For selecting data to be received from the first core 110, the read controller 180 is configured to receive the write address waddr from the write controller 130. As discussed above, the write address waddr identifies the transmit flip-flop that has data to be transferred to the second core 150. The read controller 180 generates a read address raddr identifying the transmit flip-flop having the next data to be read, and provides the read address raddr to the decoder 170. The decoder 170 generates a select signal sel (based on the read address raddr) for the multiplexer 160 to couple the MUX input (coupled to the flip-flop identified by the read address raddr) to the MUX output. As a consequence, the corresponding data is produced at the output of the multiplexer 160 (also at the data input (D) of the receive flip-flop FF).

The read controller 180 is further configured to generate a read enable signal r̅e̅ to cause the read clock generator 190 to generate (ungate) the read clock signal rclk. The receive flip-flop FF transfers the data from its data input (D) to its data output (Q) to produce an output data dout in response to a triggering portion (e.g., edge) of the read clock signal rclk during each functional mode cycle.

After the transfer or reading of the data is complete, the read controller 180 sends the read address raddr to the write controller 130. As previously discussed, the write controller 130 makes the transmit flip-flop identified by the read address raddr available to receive new input data din. The process of transferring data from the first core 110 to the second core 150 is repeated as discussed above as long as there is valid data to be transmitted.

FIG. 1 illustrates only a single-bit portion of the digital interface 100. It shall be understood that the digital interface 100 may process a set of bits (e.g., 256 bits). As such, the portion of the digital interface 100 including the FIFO 120, level shifters LS_0 to LS_N (if present), multiplexer 160, and receive flip-flop FF would be repeated for the remaining bits of the set.

As discussed above, the digital interface 100 may be operated in functional mode. In functional mode, real data din is transferred from the first core 110 to the second core 150. The transfer of the real data from the first core 110 to the second core 150 is a false path or a multi-cycle path. That is, the transfer of real data from the first core 110 to the second core 150 requires two functional mode cycles: (1) a first cycle to transfer data from the input to the output of the FIFO memory 120; and (2) a second cycle to transfer data from the output of the FIFO 120 to the output of the receive flip-flop FF. Put it another way, the input data din is not transferred to the output data dout based on the same clock signal being applied to both the selected transmit flip-flop and the receive flip-flop FF.

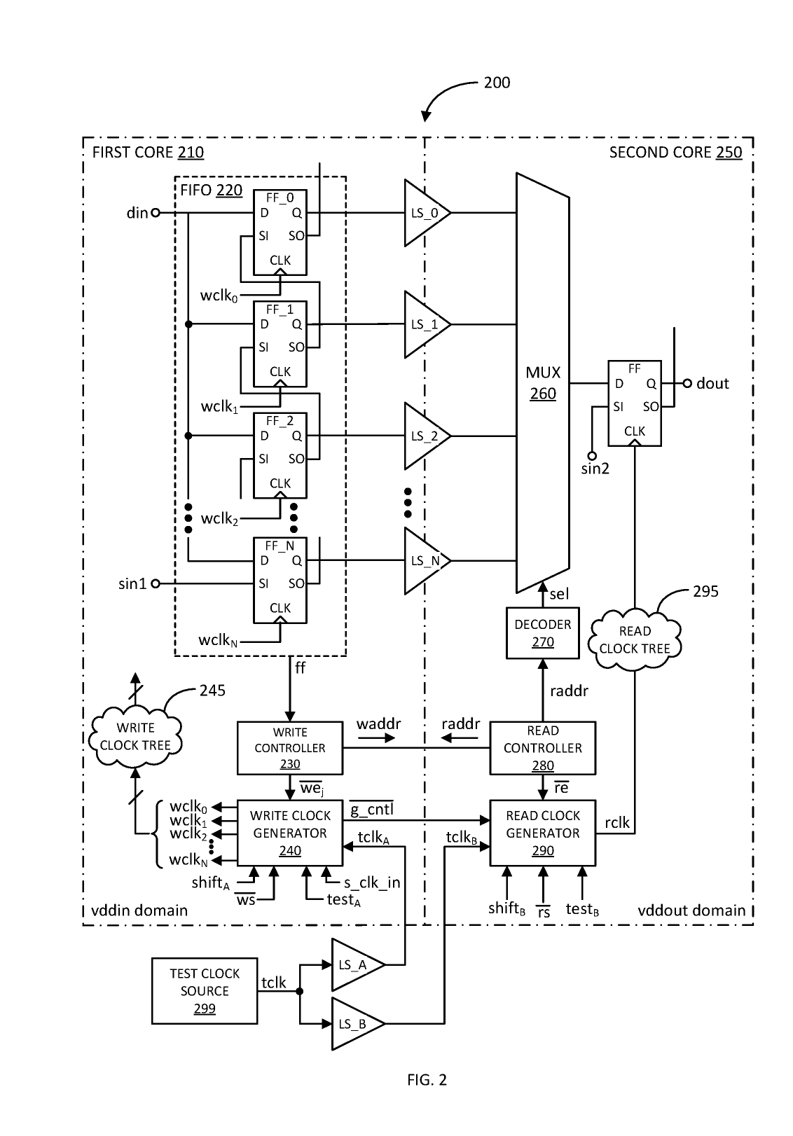

FIG. 2 illustrates a block diagram of another exemplary digital interface 200 in accordance with another aspect of the disclosure. In addition to being operated in functional mode, the digital interface 200 includes a design for testability (DFT) implementation. In a DFT implementation, the digital interface 200 is configured to operate in test modes, such as scan shift mode and scan capture mode.

In particular, the digital interface 200 includes a first core 210 and a second core 250. The first core 210 includes a FIFO memory 220 with a set of transmit flip-flops FF_0 to FF_N. Similar to the transmit flip-flops of digital interface 100, each of the set of transmit flip-flops FF_0 to FF_N includes a data input (D) for receiving input data din in functional mode. The set of transmit flip-flops FF_0 to FF_N includes clock inputs (CLK) for receiving write clock signals wclk₀ to wclk_{N}, respectively. In functional mode, the set of transmit flip-flops FF_0 to FF_N transfer the data from their common data inputs (D) to their respective data outputs (Q) in response to triggering portions (e.g., edges) of the write clock signals wclk₀ to wclk_{N}, respectively. Only one bit of input data din is transferred from the input (D) to the output (Q) of the selected flip-flop FF_j during each functional mode cycle.

For testing purposes, each of the transmit flip-flops FF_0 to FF_N includes a scan input (SI) and a scan output (SO). In this example, the scan inputs (SI) and outputs (SO) are daisy chained from flip-flop to flip-flop. For instance, a test pattern may be introduced into the scan input (SI) of flip-flop FF_N. The scan output (SO) of flip-flop FF_N is coupled to the scan input (SI) of flip-flop FF_(N−1) (not shown). Similarly, the scan output (SO) of flip-flop FF_2 is coupled to the scan input (SI) of flip-flop FF_1, and continues in a daisy chain to the scan output (SO) of flip-flop FF_0 in FIFO memory 220.

The scan output (SO) of the flip-flop FF_0 may be coupled to a scan input (SI) of a flip-flop FF_N of a FIFO memory associated with another bit or externally to a test equipment to receive the propagated test pattern for analysis. Although, in this example, the scan path is daisy chained from flip-flop FF_N to flip-flop FF_0, it shall be understood that the scan path may be daisy chained in the opposite direction, or connected in any order.

The first core 210 further includes a write controller 230 and write clock generator 240. In functional mode, the write controller 230 and write clock generator 240 operate in the same manner as discussed above with respect to write controller 130 and write clock generator 140 of digital interface 100. Further, in accordance with this example, the first core 210 includes a write clock tree 245 for routing the write clock signals wclk₀ to wclk_{N} from the write clock generator 240 to the clock inputs (CLK) of the transmit flip-flops FF_0 to FF_N, respectively.

Similarly, the second core 250 includes a multiplexer (MUX) 260, a receive flip-flop FF, a decoder 270, a read controller 280, and a read clock generator 290. Because the digital interface 200 has a DFT configuration, the receive flip-flop FF includes a scan input (SI) and a scan output (SO). A test pattern may be introduced into the scan input (SI) of the receive flip-flop FF. The scan output (SO) of the receive flip-flop FF may be coupled to a scan input (SI) of a receive flip-flop FF of another bit or externally to a test equipment to receive the propagated test pattern for analysis.

The remaining elements, namely the multiplexer (MUX) 260, the decoder 270, the read controller 280, and the read clock generator 290 operate in substantially the same manner in functional mode as the corresponding elements in digital interface 100 previously discussed. The second core 250 includes a read clock tree 295 for routing the read clock signal rclk from the read clock generator 290 to the clock input (CLK) of the receive flip-flop FF.

In scan shift mode, test pattern samples are written into the scan inputs (SI) of the transmit flip-flops of the digital interface 200 via input sin1, and test pattern samples are written to the outputs (Q) of the receive flip-flops of the digital interface 200 via input sin2. The test pattern samples written to the outputs (Q) of the receive flip-flops is to configure their respective outputs (Q) to include logic states opposite of what is expected to be written in the next scan capture cycle. As an example, if the next data to be written to the output (Q) of the receive flip-flop FF is a logic one (1), during the previous scan shift cycle, a test sample having a logic zero (0) is written to the output (Q) of the receive flip-flop. Similarly, if the next data to be written to the output (Q) of the receive flip-flop FF is a logic zero (0), during the previous scan shift cycle, a test sample having a logic one (1) is written to the output (Q) of the receive flip-flop.

In scan capture mode, the digital interface 200 is operated, based on the loaded test pattern samples in the scan shift mode, to test the interface to determine whether there are any processing errors, such as a stuck at zero (0) error or a stuck at one (1) error. A stuck at zero (0) error occurs when a particular port of a logic device is stuck at a logic zero (0) and is not producing the appropriate logic level based on the intended function of the logic being tested. Similarly, a stuck at one (1) error occurs when a particular port of a logic device is stuck at a logic one (1) and is not producing the appropriate logic level based on the intended function of the logic being tested.

In scan shift and scan capture modes, an external test clock source 299 is provided to generate a test clock signal tclk. A pair of external level shifters LS_A and LS_B may be provided to level shift the test clock signal tclk to voltage levels according to the first and second voltage domains vddin and vddout, respectively. The test clock signal tclk_{A} in the first voltage domain vddin is applied to the write clock generator 240. The test clock signal tclk_{B} in the second voltage domain vddout is applied to the read clock generator 290.

The write clock generator 240 generates one or more of the write clock signals wclk₀ to wclk_{N} based on the test clock tclk_{A}. The read clock generator 290 generates the read clock rclk based on the test clock tclk. However, because the write clock tree 245 of the first core 210 is generally substantially different than the read clock tree 295 of the second core 250, there is typically a large skew between the selected write clock signal wclkⱼ and the read clock signal rclk. Accordingly, the transfer of the test sample from the FIFO memory 220 to the receive flip-flop FF cannot be done in a true path manner (i.e., transferring data using the same clock signal without hold and setup time violations). In the past, errors in paths between cores of a digital interface have been ignored during testing, which results in reduced test coverage of the digital interface.

In summary, one of the concepts disclosed herein is to gate or suppress one of the clock signals (wclkⱼ or rclk) during a scan capture clock cycle in scan capture mode. In this regard, the write clock generator 240 is configured to generate or ungate a selected one of the clock signals (e.g., wclkⱼ) (and suppress or gate the non-selected write clock signals) and the read clock generator 290 is configured to suppress or gate the read clock signal rclk during a particular scan capture clock cycle. Similarly, the write clock generator 240 is configured to suppress or gate all of the write clock signals wclk₀ to wclk_{N} and the read clock generator 290 is configured to generate or ungate the read clock signal rclk during another scan capture clock cycle. In other words, the write clock signal wclkⱼ and the read clock signal rclk are mutually exclusive during each scan capture cycle.

Thus, by having mutually exclusive write and read clock signals in scan capture mode, there are no hold and setup timing violations as there is no true path between the first core 210 and the second core 250. In other words, there is a false path or multicycle path between the first core 210 and the second core 250. For example, during a first scan capture cycle where selected write clock signal wclkⱼ is generated (ungated) and the read clock signal is suppressed (gated), a test sample is transferred from the data input (SI) to the output (Q) and output (SO) of the selected transmit flip-flop FF_j. During a second scan capture cycle where all the write clock signal wclk₀ to wclk_{N} are suppressed (gated) and the read clock signal is generated (ungated), a test sample is transferred from the output (Q) of the selected transmit flip-flop FF_j (or corresponding input of the multiplexer 260) to the output (Q) and scan output (SO) of the receive flip-flop FF.

In this regard, the write clock generator 240 includes a scan input for receiving a test pattern s_clk_in that controls which of the clock signal (wclkⱼ or rclk) is generated (ungated) and which of the other clock signal (rclk or wclkⱼ) is suppressed (gated) during a particular scan capture cycle. The write clock generator 240 generates and sends a complementary gating control signal g̅_̅c̅n̅t̅l̅ to the read clock generator 290 for controlling generation or suppression of the read clock signal rclk based on the test pattern s_clk_in. For example, as discussed in more detail below with an exemplary embodiment, if the test pattern sample s_clk_in is a logic zero (0) for a particular scan capture cycle, the read clock signal rclk is generated (ungated) and the write clock signals wclk₀ to wclk_{N} are suppressed (gated) during that cycle. Conversely, if the test pattern sample s_clk_in is a logic one (1) for a particular scan capture cycle, a selected write clock signal wclkⱼ is generated (ungated) and the read clock signal rclk is suppressed.

The write clock generator 240 further includes inputs for configuring the write clock generator to operate in scan shift mode and scan capture mode. For instance, the write clock generator 240 includes an input to receive a test enable signal test_{A}, an input to receive a scan shift mode enable signal shift_{A} an input to receive a clock control test pattern s_clk_in, and an input to receive an enable signal w̅s̅ associated with generating the write clock signals wclk₀ to wclk_{N} during scan shift mode.

When the test_{A} and shift_{A} signals are both asserted (e.g., both logic ones (1s)), the write clock generator 240 operates in scan shift mode for shifting in the test pattern s_clk_in. When the test_{A}, and shift_{A} signals are both asserted (e.g., both logic ones (1s)) and signal w̅s̅ is asserted (e.g., at a logic zero (0)), the write clock generator 240 operates in scan shift mode for shifting in the test pattern sin1. When the test_{A} signal is asserted and the shift_{A} and r̅s̅ signals are not asserted, the write clock generator 240 operates in scan capture mode. The subscript “A” in the test_{A} and shift_{A} signals means that these signals are in the first voltage domain vddin. Although not indicated as such, the enable signal w̅s̅ is in the first voltage domain vddin.

Similarly, the read clock generator 290 includes inputs for configuring the read clock generator to operate in scan shift mode and scan capture mode. For instance, the read clock generator 290 includes an input to receive a test_{B} signal, an input to receive a shift_{B} signal, and an input to receive an enable signal r̅s̅. When the test_{B} and shift_{B} signals are both asserted (e.g., both logic ones (1s)) and the r̅s̅ signal is asserted (e.g., at a logic zero (0)), the read clock generator 290 operates in scan shift mode for shifting in the test pattern sin2. When the test_{B} signal is asserted and the shift_{B} and r̅s̅ signals are not asserted, the read clock generator 290 operates in scan capture mode. The signals test_{B}, shift_{B}, r̅s̅ signals have voltage levels according to the second voltage domain vddout.

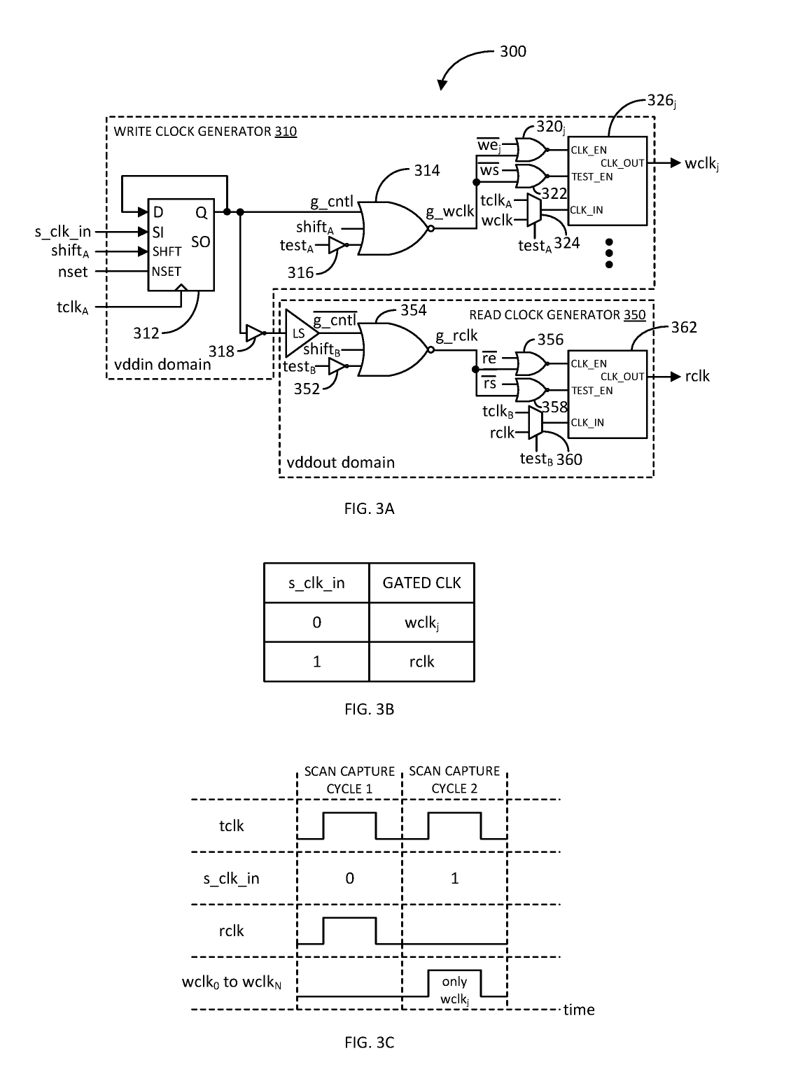

FIG. 3A illustrates a block diagram of an exemplary clock control subsystem 300 of a digital interface in accordance with another aspect of the disclosure. The subsystem 300 includes a write clock generator 310 and a read clock generator 350. The write clock generator 310 may be an exemplary detailed implementation of the write clock generator 240 previously discussed. Similarly, the read clock generator 350 may be an exemplary detailed implementation of the read clock generator 290 previously discussed.

The write clock generator 310 includes a flip-flop 312, a first NOR gate 314, a first inverter 316, a second inverter 318, a set of second NOR gates 320₀ to 320_{N} (only the jth NOR gate 320ⱼ is shown for simplicity sake), a third NOR gate 322, a multiplexer 324, and a set of clock gating circuits 326₀ to 326_{N} (only the jth clock gating circuit 326ⱼ is shown for simplicity sake).

The flip-flop 312 includes a data output (Q) coupled to a data input (D) to form a feedback loop. The flip-flop 312 further includes a scan input (SI) configured to receive the clock control test pattern s_clk_in. The flip-flop 312 further includes an enable input (SHFT) configured to receive the shift_{A} signal, a reset input (NSET) configured to receive a reset signal nset, and a clock input (CLK) configured to receive the tclk_{A} test clock signal.

The data output (Q) of the flip-flop 312 is configured to generate a gating control signal g_cntl. The g_cntl signal is applied to a first input of the first NOR gate 314 and an input of the second inverter 318. The first NOR gate 314 includes a second input configured to receive the shift_{A} signal, and a third input configured to receive an inverted test_{A} signal via the first inverter 316. The first NOR gate 314 includes an output coupled to respective first inputs of the set of second NOR gates, as represented by NOR gate 320ⱼ. The output of the first NOR gate 314 is also coupled to a first input of the third NOR gate 322.

The set of second NOR gates 320j includes second inputs configured to receive the set of write enable signals w̅e̅_̅{̅J̅}̅ generated by the write controller 230, respectively. The third NOR gate 322 includes a second input configured to receive the enable signal w̅s̅. The multiplexer 324 includes a first input configured to receive the test clock signal tclk_{A}, a second input configured to receive a base write clock signal wclk, and a select input configured to receive the test_{A} signal.

The second NOR gate 320 includes an output coupled to a clock enable input (CLK_EN) of each of the set of clock gating circuits 326ⱼ. The third NOR gate 322 includes an output coupled to a test enable input (TEST_EN) of each of the set of clock gating circuits 326ⱼ. And, the multiplexer 324 includes an output coupled to a clock input (CLK_IN) of each of the set of clock gating circuits 326ⱼ. The clock gating circuits 326ⱼ each includes a clock output (CLK_OUT) configured to produce the corresponding write clock signal wclkⱼ. As there are N+1 write clock signals wclk₀ to wclk_{N}, the write clock generator 310 may include N+1 instances of the clock gating circuit 326ⱼ and the second NOR gate 320ⱼ.

The read controller 350 includes a level shifter LS, an inverter 352, a first NOR gate 354, a second NOR gate 356, a third NOR gate 358, a multiplexer 360, and a clock gating circuit 362. The level shifter LS includes an input coupled to an output of the second inverter 318 of the write clock generator 310. As the second inverter 318 receives the g_cntl signal in the first voltage domain vddin generated at the output (Q) of the flip-flop 312, the level shifter LS is configured to generate a complementary gating signal g̅_̅c̅n̅t̅l̅ in the second voltage domain vddout.

The output of the level shifter LS is coupled to a first input of the first NOR gate 354. The first NOR gate 354 includes a second input configured to receive the shift_{B} signal, and a third input configured to receive an inverted test_{B} signal via the inverter 352. The first NOR gate 354 includes an output coupled to respective first inputs of the second and third NOR gates 356 and 358.

The second NOR gate 356 includes a second input configured to receive the read enable r̅e̅ signal generated by the read controller 280. The third NOR gate 358 includes a second input configured to receive the enable r̅s̅ signal. The multiplexer 360 includes a first input configured to receive the tclk_{B} test clock signal, a second input configured to receive a read signal rclk, and a select input configured to receive the test_{B} signal.

The second NOR gate 356 includes an output coupled to a clock enable input (CLK_EN) of the clock gating circuit 362. The third NOR gate 358 includes an output coupled to a test enable input (TEST_EN) of the clock gating circuit 362. And, the multiplexer 360 includes an output coupled to a clock input (CLK_IN) of the clock gating circuit 362. The clock gating circuit 362 includes a clock output (CLK_OUT) configured to produce the read clock signal rclk.

FIG. 3B illustrates a table depicting the clock control test pattern signal s_clk_in and corresponding gated clock signal associated with an operation of the clock control subsystem 300 in accordance with another aspect of the disclosure.

According to the table, when the test pattern sample s_clk_in is a logic zero (0) during a scan capture cycle, the read clock signal rclk is generated (ungated) and the write clock signals wclk₀ to wclk_{N} is suppressed (gated). For instance, with reference to FIG. 3A, after the logic zero (0) test pattern sample s_clk_in has been shifted to the output (Q) of the flip-flop 312 in shift scan mode, the gate control signal g_cntl is at a logic zero (0) and the complementary gate control signal g̅_̅c̅n̅t̅l̅ is at a logic one (1). The test_{A} and test_{B} are at logic ones (1s) and the shift_{A} and shift_{B} are at logic zeros (0s) in scan capture mode. Accordingly, the inputs of NOR gate 314 are all at logic zeros (0s) and one of the inputs (i.e., g̅_̅c̅n̅t̅l̅) of NOR gate 354 is at a logic one (1). Thus, NOR gate 314 outputs a logic one (1) and NOR gate 354 outputs a logic zero (0).

In scan capture mode, a selected write enable signal w̅e̅_̅{̅J̅}̅ and the read enable signal r̅e̅ are both at logic zeros (0s). Since the inputs to the NOR gate 320 are at logic one (1) (g_wclk) and logic zero (0) (w̅e̅_̅{̅J̅}̅), the NOR gate 320 outputs a logic zero (0). Since the inputs to the NOR gate 356 are both at logic zeros (0s) (g̅_̅c̅n̅t̅l̅ and r̅e̅), the NOR gate 356 outputs a logic one (1). Since the clock enable input (CLK_EN) of clock gating circuit 326ⱼ is at a logic zero (0), the clock gating circuit 326ⱼ does not generate or gate the write clock signal wclkⱼ. However, since the clock enable input (CLK_EN) of clock gating circuit 362 is at a logic one (1), the clock gating circuit 362 generates or ungates the read clock signal rclk.

With reference again to the table in FIG. 3B, when the test pattern sample s_clk_in is at a logic one (1), a selected write clock signal wclkⱼ is generated or ungated (the non-selected the write clock signals are suppressed or gated) and the read clock signal is suppressed or gated. For instance, after the logic one (1) of the test pattern sample s_clk_in has been shifted to the output (Q) of the flip-flop 312 in shift scan mode, the gate control signal g_cntl is at a logic one (1) and the complementary gate control signal g̅_̅c̅n̅t̅l̅ is at a logic zero (0). Again, the test_{A} and test_{B} are at logic ones (1s) and the shift_{A} and shift_{B} are at logic zeros (0s) in scan capture mode. Accordingly, one of the inputs (i.e., g_cntl) of NOR gate 314 is at a logic one (1), and all the inputs of NOR gate 354 are at logic zeros (0s). Thus, NOR gate 314 outputs a logic zero (0) and NOR gate 354 outputs a logic one (1).

Again, in scan capture mode, a selected (asserted) write enable signal w̅e̅_̅{̅J̅}̅ and the read enable signal r̅e̅ are both at logic zeros (0s). Since the inputs to the corresponding NOR gate 320ⱼ are both at logic zeros (0s) (g_wclk and w̅e̅_̅{̅J̅}̅), the NOR gate 320ⱼ outputs a logic one (1). Since the inputs to the NOR gate 356 are at logic one (1) and zero (0) (g̅_̅c̅n̅t̅l̅ and r̅e̅), the NOR gate 356 outputs a logic zero (0). Since the clock enable input (CLK_EN) of clock gating circuit 326ⱼ is at a logic one (1), the clock gating circuit 326ⱼ generates or ungates the write clock signal wclkⱼ. Since the clock enable input (CLK_EN) of clock gating circuit 362 is at a logic zero (0), the clock gating circuit 362 suppresses or gates the read clock signal rclk.

In above scenario, the unselected (deasserted) write enable signals are at logic ones (1s). Accordingly, the corresponding ones of the set of second NOR gates outputs logic zeros (0s). As a result, the corresponding ones of the set of clock gating circuits suppress or gate the unselected write clock signals.

FIG. 3C illustrates a graph depicting several exemplary signals associated with an operation of the clock control subsystem 300 in accordance with another aspect of the disclosure. The vertical or y-axis of the graph depicts several rows of signals, including the test clock signal tclk, the clock control test pattern signal s_clk_in, the read clock signal rclk, and the write clock signals wclk₀ to wclk_{N}. The horizontal or x-axis represents time.

In this example, two scan capture cycles are depicted: scan capture cycle 1 in the first (left) column and scan capture cycle 2 in the second (right) column. A scan capture cycle may be defined as one period of the test clock signal tclk when the test_{A}/test_{B} signal is at a logic one (1) (i.e., test mode) and the shift_{A}/shift_{B} is at a logic zero (0) (i.e., scan capture mode). Thus, as depicted in the first row of the graph, scan capture cycle 1 coincides with a first period of the test clock signal tclk, and scan capture cycle 2 coincides with a second period (immediately following the first period) of the test clock signal tclk.

According to this example, as depicted in the second row of the graph, the clock control test pattern signal s_clk_in is at a logic zero (0) during scan capture cycle 1, and at a logic one (1) during scan capture cycle 2. As depicted in the third row of the graph, the read clock signal rclk is generated (ungated) during scan capture cycle 1 and is suppressed (gated) during scan capture cycle 2. As depicted in the fourth row of the graph, all the write clock signals wclk₀ to wclk_{N} are suppressed (gated) during scan capture cycle 1 and only the selected write clock signal wclkⱼ is generated (ungated) during scan capture cycle 2.

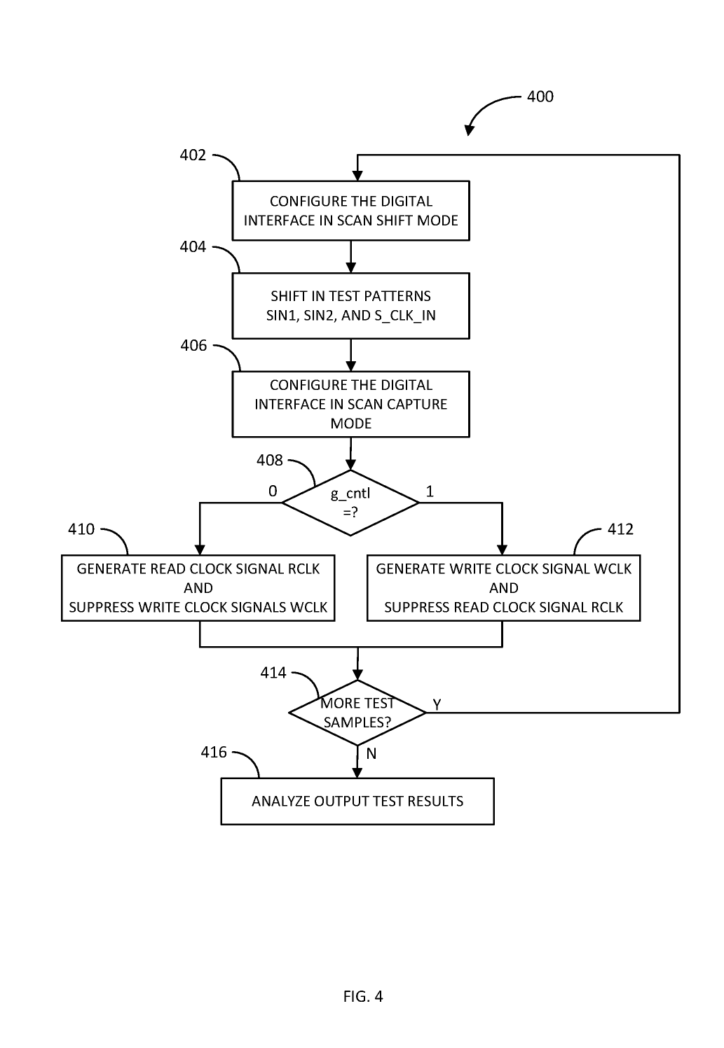

FIG. 4 illustrates a flow diagram of an exemplary method 400 of testing the digital interface 200 in accordance with another aspect of the disclosure. The method 400 includes configuring the digital interface 200 in scan shift mode (block 402). In this regard, the test_{A}/test_{B} signals may be asserted (e.g., set to logic ones (1s)) to configure the digital interface 200 in test mode. For instance, with reference to FIG. 3A, the testA/testB being at logic ones (1s) effectively enables the NOR gates 314 and 354, and causes the multiplexers 324 and 360 to select the test clock signals tclk_{A} and tclk_{B}, respectively.

The shift_{A}/shift_{B} signals, and the w̅s̅/r̅s̅ signals may be configured to clock in the clock control test pattern s_clk_in, test pattern sin1, and test pattern sin2, respectively. For instance, when the shift_{A} signal is asserted (set to logic one (1)), the flip-flop 312 is enabled so that the s_clk_in bit is transferred from the (SI) input to the (Q) output of the flip-flop 312. When the shift_{A}/shift_{B} are asserted (set to logic ones (1s)) and w̅s̅/r̅s̅ signals are asserted (set to logic zeros (s)), the NOR gates 314 and 354 generate the g_wclk and g_rclk at logic zeros (0s) and the NOR gates 322 and 358 generate logic ones (1). As a consequence, all the write clocks signals wclk₀ to wclk_{N} are generated or ungated to scan the test pattern sin1 into the FIFO memory 210. The read write clock signal rclk is generated or ungated to scan the test pattern sin2 into the receive flip-flop FF.

Thus, as a consequence of configuring the digital interface 200 in scan shift mode, the method 400 includes shifting in the test patterns sin1, sin2, and s_clk_in (block 404).

The method 400 further includes configuring the digital interface 200 in scan capture mode (block 406). In this regard, shift_{A} and shift_{B} signals are deasserted (set to logic zeros (0s)). The shift_{A} signal being at a logic zero (0) disables the flip-flop 312 so that the g_cntl signal at the output (Q) is maintained during the scan capture cycle. The shift_{A} and shift_{B} signals are deasserted (e.g., set to logic zeros (0s)) to effectively enable the NOR gates 314 and 354 so that the g_cntl and g̅_̅c̅n̅t̅l̅ signals determine the outputs of the NOR gates 314 and 354, respectively.

Accordingly, the method 400 further includes determining the state of the g_cntl signal (which is the shifted in test pattern sample s_clk_in) (block 408). If the g_cntl signal is determined to be a logic zero (0), the method 400 includes generating or ungating the read clock signal rclk and suppressing or gating the write clock signals wclk₀ to wclk_{N} during the current scan capture cycle (block 410). Thus, with regard to digital interface 200, the read clock generator 290 generates the read clock signal rclk and the write clock generator 240 suppresses all the write clock signals wclk₀ to wclk_{N}. With regard to the clock control subsystem 300, the clock gating circuits 326 suppresses or gates the write clock signals wclk₀ to wclk_{N}, and the clock gating circuit 362 generates or ungates the read clock signal rclk. The generation of the read clock signal rclk causes the receive flip-flop to transfer the data at its input (D) to the output (Q) as dout during the current scan capture cycle.

If, on the other hand, the g_cntl signal is determined to be a logic one (1), the method 400 includes suppressing or gating the read clock signal rclk and generating or ungating the selected write clock signal wclkⱼ during the current scan capture cycle (block 412). Thus, with regard to digital interface 200, the write clock generator 220 generates only the selected clock signal wclkⱼ and the read clock generator 290 suppresses the read clock signal rclk. With regard to the clock control subsystem 300, the selected clock gating circuit 326ⱼ generates the selected write clock signal wclkⱼ, and the clock gating circuit 362 suppresses the read clock signal rclk. The gating of the selected write clock signal wclkⱼ causes the transfer of the data from the input (SI) to the output (Q) of the corresponding transmit flip-flop FF_j during the current scan capture cycle.

The method 400 further includes determining whether there are more test pattern samples to clock in (block 414). If, in block 414, it is determined that there are more test pattern samples to clock in, the method 400 proceeds to block 402 to perform another scan shift mode operation, and proceeds therefrom to perform the operations indicated in blocks 404 through 414 as previously discussed. If, on the other hand, in block 414, it is determined that there are no more test pattern samples to clock in, the method 400 includes shifting out and analyzing the test results (block 416).

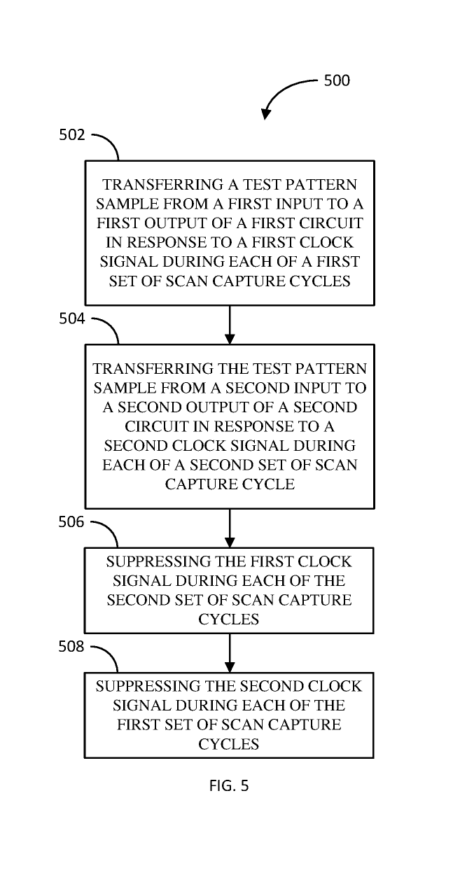

FIG. 5 illustrates a flow diagram of another exemplary method 500 of testing a digital interface in accordance with another aspect of the disclosure. In this example, the digital interface includes a first circuit (e.g., a portion of the first core 210), and a second circuit (e.g., a portion of the second core 250).

The method 500 includes transferring a test pattern sample from a first input to a first output of a first circuit in response to a first clock signal during each of a first set of scan capture cycles (block 502). An example of a means for transferring a test pattern sample from a first input to a first output of a first circuit in response to a first clock signal during each of a first set of scan capture cycles is a transmit flip-flop FF_j.

The method 500 further includes transferring the test pattern sample from a second input to a second output of a second circuit in response to a second clock signal during each of a second set of scan capture cycle (block 504). An example of a means for transferring the test pattern sample from a second input to a second output of a second circuit in response to a second clock signal during each of a second set of scan capture cycle includes the receive flip-flop FF.

The method 500 also includes suppressing the first clock signal during each of the second set of scan capture cycles (block 506). Examples of means for suppressing the first clock signal during each of the second set of scan capture cycles include the write clock generators 240 and 310.

Additionally, the method 500 includes suppressing the second clock signal during each of the first set of scan capture cycles (block 508). Examples of means for suppressing the second clock signal during each of the first set of scan capture cycles include the read clock generators 290 and 350.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. An apparatus, comprising:
a first circuit including a first input and a first output; and
a first clock generator configured to generate a first clock signal, wherein the first circuit is configured to transfer a test pattern sample from the first input to the first output in response to the first clock signal during each of a first set of scan capture cycles;
a second circuit including a second input and a second output; and
a second clock generator configured to generate a second clock signal, wherein the second circuit is configured to transfer the test pattern sample from the second input to the second output in response to the second clock signal during each of a second set of scan capture cycle;
wherein the first clock generator is configured to suppress the first clock signal during each of the second set of scan capture cycles, and wherein the second clock generator is configured to suppress the second clock signal during each of the first set of scan capture cycles.

2. The apparatus of claim 1, wherein the first clock generator is configured to generate the first clock signal based on a third clock signal, and wherein the second clock generator is configured to generate the second clock signal based on the third clock signal.

3. The apparatus of claim 2, wherein a duration of each of the first set of scan capture cycles or each of the second set of scan capture cycles is based on a period of the third clock signal.

4. The apparatus of claim 1, wherein the first clock generator is configured to generate the first clock signal and the second clock generator is configured to suppress the second clock signal during the first set of scan capture cycles based on a first subset of samples of a test pattern.

5. The apparatus of claim 4, wherein the second clock generator is configured to generate the second clock signal and the first clock generator is configured to suppress the first clock signal during the second set of scan capture cycles based on a second subset of samples of the test pattern.

6. The apparatus of claim 1, wherein the second clock generator is configured to generate the second clock signal and the first clock generator is configured to suppress the first clock signal during the second set of scan capture cycles based on samples of a test pattern, respectively.

7. The apparatus of claim 1, wherein the first clock generator is configured to generate the first clock signal and the second clock generator is configured to generate second clock signal during each of a set of scan shift cycles.

8. The apparatus of claim 1, wherein the test pattern sample transferred from the first input to the first output of the first circuit is in a first voltage domain.

9. The apparatus of claim 8, wherein the test pattern sample transferred from the second input to the second output of the second circuit is in a second voltage domain, wherein the second voltage domain is different than the first voltage domain.

10. The apparatus of claim 1, wherein the first circuit is configured to transfer data from a third input to the first output in response to the first clock signal during each of a first set of functional mode cycles.

11. The apparatus of claim 10, wherein the second circuit is configured to transfer the data from the second input to the second output in response to the second clock signal during a second set of functional mode cycles.

12. The apparatus of claim 1, wherein the second circuit is configured to transfer another test pattern sample from a third input to the second output in response to the second clock signal during each of a set of scan shift cycles.

13. A method, comprising:
transferring a test pattern sample from a first input to a first output of a first circuit in response to a first clock signal during each of a first set of scan capture cycles;
transferring the test pattern sample from a second input to a second output of a second circuit in response to second clock signal during each of a second set of scan capture cycle;
suppressing the first clock signal during each of the second set of scan capture cycles; and
suppressing the second clock signal during each of the first set of scan capture cycles.

14. The method of claim 13, further comprising:
generating the first clock signal based on a third clock signal; and
generating the second clock signal based on the third clock signal.

15. The method of claim 14, wherein a duration of each of the first set of scan capture cycles or each of the second set of scan capture cycles is based on a period of the third clock signal.

16. The method of claim 13, further comprising generating the first clock signal and suppressing the second clock signal during each of the first set of scan capture cycles based on a first subset of samples of a test pattern.

17. The method of claim 16, further comprising generating the second clock signal and suppressing the first clock signal during each of the second set of scan capture cycles based on a second subset of samples of the test pattern.

18. The method of claim 13, further comprising generating the second clock signal and suppressing the first clock signal during the second set of scan capture cycles based on samples of a test pattern, respectively.

19. The method of claim 13, further comprising generating the first clock signal and the second clock signal during each of a set of scan shift cycles.

20. The method of claim 13, wherein the test pattern sample transferred from the first input to the first output of the first circuit is in a first voltage domain

21. The method of claim 20, wherein the test pattern sample transferred from the second input to the second output of the second circuit is in a second voltage domain, wherein the second voltage domain is different than the first voltage domain.

22. The method of claim 13, further comprising transferring data from a third input to the first output in response to the first clock signal during each of a first set of functional mode cycles.

23. The method of claim 22, further comprising transferring the data from the second input to the second output in response to the second clock signal during a second set of functional mode cycles.

24. The method of claim 13, further comprising transferring another test pattern sample from a third input to the second output of the second circuit in response to the second clock signal during each of a set of scan shift cycles.

25. An apparatus, comprising:
means for transferring a test pattern sample from a first input to a first output of a first circuit in response to a first clock signal during each of a first set of scan capture cycles;
means for transferring the test pattern sample from a second input to a second output of a second circuit in response to second clock signal during each of a second set of scan capture cycle;
means for suppressing the first clock signal during each of the second set of scan capture cycles; and
means for suppressing the second clock signal during each of the first set of scan capture cycles.

26. The apparatus of claim 25, further comprising:
means for generating the first clock signal based on a third clock signal; and
means for generating the second clock signal based on the third clock signal.

27. The apparatus of claim 26, wherein a duration of each of the first set of scan capture cycles or each of the second set of scan capture cycles is based on a period of the third clock signal.

28. The apparatus of claim 25, further comprising means for generating the first clock signal and suppressing the second clock signal during each of the first set of scan capture cycles based on a first subset of samples of a test pattern.

29. The apparatus of claim 28, further comprising means for generating the second clock signal and suppressing the first clock signal during each of the second set of scan capture cycles based on a second subset of samples of the test pattern.

30. The apparatus of claim 25, further comprising means for generating the second clock signal and suppressing the first clock signal during the second set of scan capture cycles based on samples of a test pattern, respectively.
